(19) United States
(12) Patent Application Publication
(10) Pub. No.: US 2013/0156199 A1
(43) Pub. Date: Jun. 20, 2013

(54) HANDHELD COMPUTING DEVICE CASE WITH AUDIO OUTPUT

(71) Applicants: John E. O'Donnell, Ft. Lauderdale, FL (US); David C. Gill, North Providence, RI (US); Daniel I. Radin, New York, NY (US)

(72) Inventors: John E. O'Donnell, Ft. Lauderdale, FL (US); David C. Gill, North Providence, RI (US); Daniel I. Radin, New York, NY (US)

(73) Assignee: ALESIS, L.P., Cumberland, RI (US)

(21) Appl. No.: 13/566,174

(22) Filed: Aug. 3, 2012

Related U.S. Application Data
(60) Provisional application No. 61/570,524, filed on Dec. 14, 2011.

(51) Int. Cl. H03G 3/00; H04R 5/00; H03G 5/00

(52) U.S. Cl. 381/17; 381/107; 381/103

(57) ABSTRACT

A case for a handheld computing device is disclosed. The case includes a housing sized and dimensioned to receive a handheld computing device securely therein. A data port is configured to electrically connect to the data connector on the handheld computing device. A microprocessor is electrically connected to the data port. The microprocessor is configured and arranged to authorize audio stored on the handheld computing device to play through the data connector and connected data port. Audio filters are electrically connected to the data port. An audio output electrically connector to the audio filters. The case provides that audio may be played through the audio output with wider gain and dynamic range than a standard integrated headphone audio jack of a handheld computing device

### CROSS-REFERENCE TO RELATED APPLICATION

This patent document claims priority to earlier filed U.S. Provisional Application Ser. No. 61/570,524, filed on Dec. 14, 2011, the entire contents of which are incorporated herein by reference.

### BACKGROUND

1. Technical Field

This patent document relates generally to protective cases for handheld computing devices, such as smartphones, and more particularly to such a case having a high quality audio output that bypasses inferior headphone outputs.

2. Background of the Related Art

Smartphones, such as the iPhone® brand smartphone, portable music players, like the iPod® Touch® brand mp3 player, and tablet devices, like the Apple iPad®, have become a popular device to store and playback music. However, there are limitations to the sound quality and power from this type of device's headphone/microphone connector. These connectors provide generally poor sound quality to the discerning audiophile due to inferior audio circuitry, signal chain and lower quality connectors. Frequently, these handheld computing devices have poor gain range and dynamic range, and could introduce harmonic distortion to the quality of the audio. These handheld computing devise also lack the flexibility to drive lower impedance headphones.

Therefore, when possible, it is desirable to obtain audio from the handheld computing devices through a direct data connection and that has the ability to drive lower impedance headphones.

There exist prior art headphone and line output adapters for handheld computing devices, but they suffer undesirable limitations. These devices are often an adapter or dongle that either attach to the bottom of the handheld computing device, or use an extension cable. In either case, the connection is not preferred for optimal audio quality. Furthermore, these types of connections also detract from the appearance of the handheld computing device because they are not form fitted therewith.

Therefore, there is a perceived need in the industry for a higher quality audio connection for handheld computing devices that does not detract from the physical appearance of the handheld computing device.

### SUMMARY

The handheld computing device case solves the problems of the prior art by providing a case for a handheld computing device, such as smartphones, portable media players, tablets, and the like, that includes an enhanced audio output that provides a robust and deep sound that audiophiles desire. Moreover, the case is configured to drive lower impedance headphones.

The case is a form-fitted to the handheld computing device, thereby complimenting the industrial design of the handheld computing device instead of detracting from it. The case receives audio from data connector and provides the user with a higher quality, more powerful, audio output than the standard headphone jack included on such handheld computing devices.

### BRIEF DESCRIPTION OF THE DRAWINGS

These and other features, aspects, and advantages of the present invention will become better understood with reference to the following description, appended claims, and accompanying drawings where:

FIG. 1 shows a front and rear perspective view, side by side, of a preferred embodiment of the handheld computing device case; and

FIG. 2 shows a schematic diagram of the electrical operation of a preferred embodiment of the handheld computing device case.

### DESCRIPTION OF THE PREFERRED EMBODIMENT

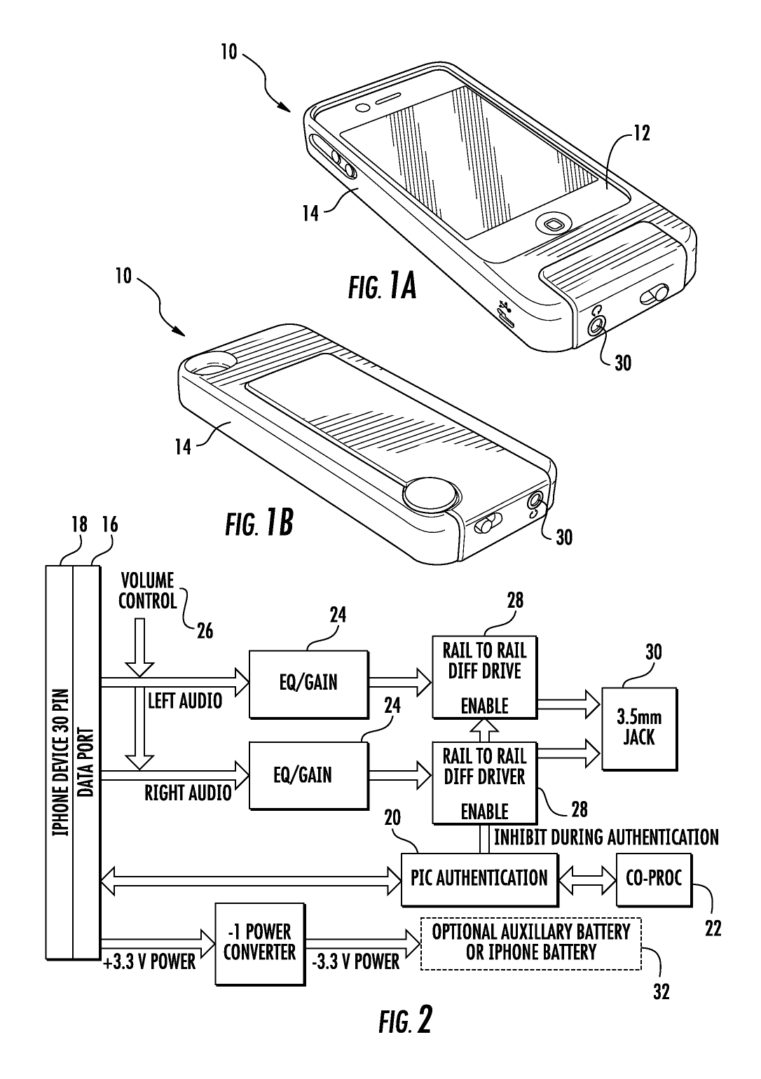

Referring now to FIGS. 1 and 2, a first embodiment of the handheld computing device case (“case”) is shown generally at 10 with a handheld computing device 12 secured therein. The case 10 includes a two-piece housing 14 that fits over a handheld computing device 12, such as a smartphone, like the iPhone® brand smartphone, electronic audio device, such as an iPod® Touch® brand music player, and tablet devices, such as the Apple iPad® brand tablet computer.

One part of the housing 14 has a data port 16 that engages the data connector 18 on the handheld computing device 12. A microprocessor 20 contained in the housing 14 communicates through the data port 16 and data connector 18 on the handheld computing device 12 to establish and authorize communication. The initial communication can occur through a slow-speed serial data connection or higher speed serial interface, such as universal serial bus interface, among others. Where needed, an authentication coprocessor 22 may be included to enable authentication of the case 10 with the handheld computing device 12.

Audio played from the handheld computing device 12 is then directed to the data connector 16 instead of the lower quality headphone output on the handheld computing device 12. The housing 14 includes high quality filters 24, such as gain and equalizer circuits, to preserve the fidelity of the audio, which is degraded in the standard headphone output. The use of these high quality filters 24 prevents harmonic distortion, and preserves a wider gain and dynamic range to the audio.

A volume control 26 and amplifier 28 is included to control the volume level of the filtered audio.

The filtered and amplified audio it directed to a headphone output 30 on the housing 14 of the case 10. Because the case 10 includes the filters 24 and amplifiers 28, the audio output of the headphone output 30 on the case 10 has higher quality audio than the integrated headphone jack on the handheld computing device 12. The amplifier 28 permits lower impedance headphones to be driven effectively.

The case 10 may use power from the handheld computing device 12 or be include its own battery 32. The battery, if included, may be configured to serve as auxiliary power for the handheld computing device 12 as well.

Therefore, it can be seen that the case 10 provides a unique solution to the problem of providing a high quality audio output to a handheld computing device 12 by providing a case 10 that obtains audio through the data connector 18 of the handheld computing device 12 rather than the inferior integrated headphone connector. The case 10 can drive lower impedance headphones and provides a wider gain and dynamic range to the audio and prevents harmonic distortion.

It would be appreciated by those skilled in the art that various changes and modifications can be made to the illustrated embodiments without departing from the spirit of the invention. All such modifications and changes are intended to be within the scope of the invention.

What is claimed:

1. A case for a handheld computing device, comprising:
a housing sized and dimensioned to receive a handheld computing device securely therein;
a data port configured to electrically connect to the data connector on the handheld computing device;
a microprocessor electrically connected to the data port, the microprocessor configured and arranged to authorize audio stored on the handheld computing device to play through the data connector and connected data port;
audio filters electrically connected to the data port; and
an audio output electrically connector to the audio filters;
whereby audio may be played through the audio output with wider gain and dynamic range than a standard integrated headphone audio jack of a handheld computing device.

2. The case of claim 1, further comprising a volume control and amplifier configured and arranged to set the level of the audio output.

3. The case of claim 1, further comprising an auxiliary battery.

4. The case of claim 1, further comprising an opening sized and dimensioned to reveal a display of the handheld computing device.

5. The case of claim 1, wherein the microprocessor redirects audio from a headphone jack on the handheld computing device to the data connector.

6. The case of claim 1, wherein the audio filters comprise gain circuits.

7. The case of claim 1, wherein the audio filters comprise equalizer circuits.

8. The case of claim 1, wherein the audio filters process stereo audio.

9. The case of claim 1, wherein the audio output further comprises a headphone output.

10. The case of claim 9, wherein the headphone output is configured and arranged to drive low impedance headphones.
